(19) United States
(12) Patent Application Publication
(10) Pub. No.: US 2025/0204105 A1
(43) Pub. Date: Jun. 19, 2025

(54) CHIP SCALE PACKAGE LIGHT-EMITTING DEVICE WITH THIN, CONFORMAL WAVELENGTH CONVERTER

(71) Applicant: LUMILEDS LLC, San Jose, CA (US)

(72) Inventor: Antonio Lopez-Julia, Vaals (NL)

(73) Assignee: LUMILEDS LLC, San Jose, CA (US)

(21) Appl. No.: 18/542,189

(22) Filed: Dec. 15, 2023

(51) Int. Cl. H01L 33/50

(52) U.S. Cl. CPC H10H 20/8514; H10H 20/0361

(57) ABSTRACT

A light-emitting device includes a transparent substrate less than 60 μm thick, a semiconductor diode structure on one surface of the substrate, and a wavelength-converting layer less than 50 μm thick on the other surface and the sidewalls of the substrate. The wavelength-converting layer includes luminescent particles having D50 less than 20 μm that are bound together or to the substrate by an inorganic coating medium less than 700 nm thick that is index-matched with the substrate. inorganic binder, optical sidewall coating, and an optical sidewall structure. The luminescent particles absorb light emitted by the semiconductor diode structure at a first wavelength and emit light at a second, longer wavelength.

### FIELD OF THE INVENTION

The field of the present invention relates to light-emitting devices, and particularly wavelength-converted light-emitting devices.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a different, typically longer wavelength. For such phosphor-converted LEDs (“pcLEDs”), the fraction of the light emitted by the LED that is absorbed by the phosphors depends on the amount of phosphor material in the optical path of the light emitted by the LED, e.g., on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

In a so-called chip-scale package, LED structure is formed on a transparent substrate, and the phosphor layer is on the opposite surface of the substrate. Output light from the LED propagates through the substrate and into the phosphor layer, while some light escapes through sidewalls of the substrate. An optical sidewall coating (e.g., titanium oxide or other suitable scattering particles in silicone or other transparent medium) can be employed to obstruct propagation of such laterally propagating light, much of which is lost as useful output of the phosphor-converted LED.

### SUMMARY

An inventive wavelength-converted light-emitting device comprising a substrate, a semiconductor diode structure, and a wavelength-converting layer. The substantially transparent substrate has opposite first and second surfaces and sidewalls connecting the first and second surfaces. Nonzero thickness the substrate is less than 60 μm. The semiconductor diode structure is positioned on the first surface of the substrate, and includes a light-emitting active region within the semiconductor diode structure that is arranged so as to emit first output light in a first output wavelength range. At least a portion of the first output light entering the substrate through the first substrate surface. The wavelength-converting layer is positioned on the second surface and the sidewalls of the substrate, and comprises a multitude of luminescent particles that are bound together or to the substrate by a transparent inorganic coating medium substantially index-matched with the substrate. Nonzero D50 characterizing the luminescent particles is less than 20 μm; nonzero thickness of the inorganic coating medium on the luminescent particles is less than 700 nm; nonzero thickness of the wavelength-converting layer is less than 50 μm. The luminescent particles absorb incident first output light exiting the substrate and emit second output light in a second output wavelength range that differs from the first output wavelength range.

Objects and advantages pertaining to wavelength-converted light-emitting devices may become apparent upon referring to the example embodiments illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic side cross-sectional view of a conventional wavelength-converted light-emitting device.

FIG. 2A is a schematic side cross-sectional view of an example of an inventive wavelength-converted light-emitting device. FIG. 2B is an enlargement of a portion of the device of FIG. 2A. FIG. 2C is an enlarged view of a portion of another example of an inventive wavelength-converted light-emitting device.

FIG. 3 is a plot of luminance with respect to position across the light-emitting device for the examples of FIGS. 1 and 2B. FIG. 4 is a similar plot for the devices of FIGS. 1, 2B and 2C.

The embodiments depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, the height, depth, or width of certain features (e.g., active layer thickness, phosphor particles, coating thickness, and so on) often can be exaggerated relative to certain other features (e.g., the thickness of a semiconductor layer or a substrate. The embodiments shown are only examples and should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the disclosure. The detailed description and drawings illustrate inventive principles by way of example, not by way of limitation.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, “substantially index-matched” or “substantially index-matched” indicates that an interface between the two media, materials, or structures in question would exhibit Fresnel reflection at normal incidence less than about 2%.

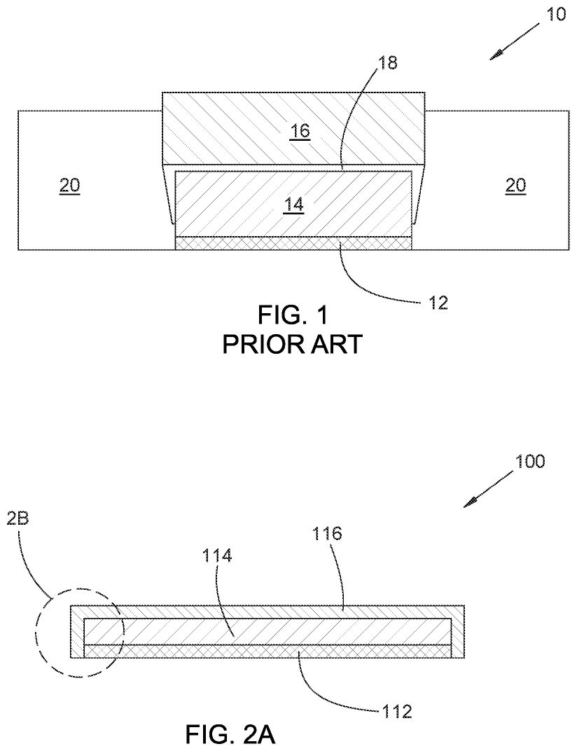

A conventional arrangement for a wavelength-converted light-emitting device 10, suitable for use in a chip scale package, is illustrated schematically in FIG. 1. A semiconductor diode structure 12 is formed on a first surface of a substantially transparent substrate 14. For purposes of the present disclosure and appended claims, “substantially transparent” shall denote a medium, material, or structure that transmits an operationally acceptable fraction of light within an operationally relevant wavelength range. Typical wavelength ranges for the devices disclosed herein fall within the near UV, visible, or near infrared portions of the electromagnetic spectrum, i.e., have a range of vacuum wavelengths that lie between about 0.30 μm and about 2.0 μm (note that a wavelength range of any given device typically is only a small fraction of that overall range). The semiconductor diode structure includes a light-emitting active region that emits first output light in a first output wavelength range; the emitted first output light propagates within the semiconductor diode structure 12 and some of the first output light exits the semiconductor diode structure 12 and enters the substrate 14. The semiconductor diode structure can include any one or more suitable semiconductor materials to produce the first output light in the desired first wavelength range. Examples of suitable materials can include but are not limited to one or more doped or undoped III-V, II-VI, or Group IV semiconductor materials, or alloys or mixtures thereof. The active region can include any one or more of those materials arranged in any suitable way, e.g., as a quantum well, multi-quantum well, quantum dots, and so forth.

The substrate 14 has the first surface, a second substrate surface opposite the first surface, and sidewalls connecting the first and second surfaces. The light-emitting device 10, and hence the semiconductor diode structure 12 and the substrate 14, are often square or rectangular, so that the substrate 14 has four distinct sidewalls. This need not be the case, however, and the substrate 14 and its sidewalls can assume any suitable or desirable shape.

A wavelength-converting layer 16 (also referred to as the phosphor layer 16) is on the second surface of the substrate 14, and is adhered to the substrate 14 by adhesive layer 18. The phosphor layer 16 includes luminescent material that absorbs at least a portion of the first output light that propagates within the layer 16 and emits second output light in a second output wavelength range. In some examples the phosphor layer 16 can comprise, e.g., a ceramic YAG film or phosphor material in a glass film. The second wavelength range is different from the first wavelength range, and typically is shifted to longer wavelengths. In some examples the phosphor layer 16 can include only a single luminescent material, while in other examples the layer 16 can include multiple different luminescent materials that emit second output light at different corresponding wavelengths. In some examples the phosphor layer 16 can be arranged to absorb all of the first output light so that optical output of the device 10 includes only the second output light. Alternatively, the layer 16 can be arranged to absorb only a portion of the first output light, so that optical output of the device 10 includes both first and second output light. Any of those arrangements of the phosphor layer 16 can be incorporated into the inventive light-emitting devices described below.

In the conventional device 10, refractive index mismatch between the adhesive layer 18 and one or both of the substrate 14 or the phosphor layer 16 can result in optical loss due to Fresnel reflection at the corresponding interfaces. In the conventional device 10, the substrate 14 and the phosphor layer 16 are each several hundred microns or even a few millimeters thick. A significant fraction of the first output light exits the substrate 14 and phosphor layer 16 through the sidewalls. Typically the phosphor layer 16 is larger in area than the semiconductor diode structure 14, so that there is some “overhang” of the phosphor layer 16 beyond the edges of the semiconductor diode structure 14. The overhang enables the phosphor layer 16 to “catch” and convert at least some of the first output light that exits the substrate through the sidewalls, increasing the total flux of the device 10 (i.e., the total emitted output power). However, increasing the area of the phosphor layer 16 often correspondingly reduces the luminance, which is undesirable in some instances. It is also generally desirable for the light-emitting devices to be smaller rather than larger, for increasing luminance or for overall compactness. The device 10 also includes an optical sidewall coating 20 surrounding the sidewalls of the semiconductor diode structure 12, the substrate 14, and the phosphor layer 16. The optical sidewall coating 20 (e.g., titanium oxide scattering particles in a silicone) obstructs lateral propagation of light the exits the substrate 14 or the phosphor layer 16 through their sidewalls, so that light is emitted by the device 10 over only the desired area, without leaking into adjacent devices or propagating in unwanted directions. Much of that light is lost, however. The thicker is the phosphor layer 16, the more optical sidewall coating material is required to obstruct the unwanted lateral light propagation, driving up overall size, weight, and cost of the device 10.

For at least these reasons, it would be desirable to provide a light-emitting device for which one or more of the following applies: (i) the phosphor layer is as thin as practicable (e.g., less than about 50 μm, while still being sufficiently thick to function as a wavelength-converting layer) to reduce the area of its sidewalls and correspondingly reduce lateral emission from the sidewalls, and to reduce size of or need for of the optical sidewall coating; (ii) the area of the phosphor layer is only minimally larger than the area of the semiconductor diode structure (e.g., overhang about equal to the phosphor layer thickness); (iii) the transparent substrate is as thin as practicable (e.g., less than 60 μm, while still being sufficiently thick to provide structural integrity to the light-emitting device for use, e.g., in a chip scale package) to reduce the area of its sidewalls and correspondingly reduce lateral emission from the sidewalls, and to reduce size of or need for the optical sidewall coating; or (iv) the index-mismatched adhesion layer can be omitted, and an index-matched coating layer binds luminescent particles together and to the substrate to form the wavelength-converting layer attached to the substrate.

U.S. Pat. Pub. No. 2022/0216378 discloses several arrangements of lateral light collectors between the substrate sidewalls and the optical side coating of a phosphor-converted LED that address one or more of the issues above. That publication is incorporated herein by reference in its entirety.

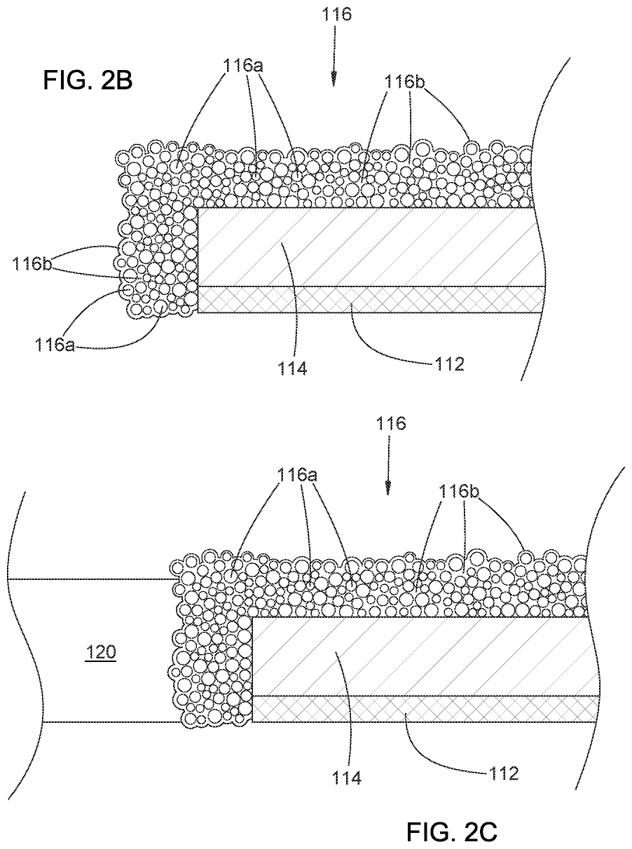

Examples of an inventive light-emitting device 100 are illustrated schematically in FIGS. 2A through 2C. A semiconductor diode structure 112 is formed on one surface of a substantially transparent substrate 114 that has a nonzero thickness that is less than about 60 μm (but is still sufficiently thick to provide structural integrity to the light-emitting device for use, e.g., in a chip scale package). In some examples the nonzero thickness of the substrate 114 can be less than about 50 μm, less than about 40 μm, less than about 30 μm, or less than about 20 μm. A phosphor layer 116 is formed on the opposite surface of the substrate 114 and has a nonzero thickness that is less than about 50 μm (but is still sufficiently thick to function as a wavelength converter). The semiconductor diode structure 114 can be of any suitable type, composition, or construction, as described above. In some examples the nonzero thickness of the phosphor layer 116 can be less than about 40 μm, less than about 30 μm, less than about 20 μm, less than about 15 μm, or less than about 10 μm.

The phosphor layer 116 comprises luminescent particles 116a that are characterized by a nonzero D50 (i.e., median transverse particle size) less than about 20 μm. In some examples the luminescent particles 116a can be characterized by a D50 that is greater than about 1 μm, greater than about 2 μm, greater than about 5 μm, greater than about 10 μm, or greater than about 15 μm. In some examples the luminescent particles 116a can be characterized by a D50 that is less than about 15 μm, less than about 10 μm, less than about 5 μm, or less than about 2 μm. The luminescent particles can be of any suitable type or composition (e.g., glass, ceramic, crystalline or polycrystalline, and so forth), and can include any suitable one or more materials that absorb the first output light in the first output wavelength range and emit the second output light in second output wavelength range. In one specific example doped YAG particles are employed to absorb blue first output light and emit yellow or red second output light. In some examples, two or more different phosphors can be employed for producing second output light in multiple corresponding wavelength ranges.

The luminescent particles 116a are bound together and adhered to the substrate 114 by being coated by a substantially transparent inorganic coating medium 116b that is substantially index-matched with the substrate 114 (visible in FIGS. 2B and 2C; layer 116 of FIG. 2A has the same structure, but too small to be seen on the scale of that drawing). At least some of the luminescent particles 116a are embedded entirely within the inorganic coating medium 116b. In some examples all of the particles 116a are embedded entirely within the inorganic coating medium 116b; in some other examples some of the particles 116a protrude from the inorganic coating medium 116b. Any one or more suitable materials can be employed for forming the inorganic coating medium 116b; suitable examples can include, e.g., semiconductor or metal oxides, nitrides, oxynitrides, or combinations or mixtures thereof. In some examples, the substrate 114 and the inorganic coating medium 116b have substantially the same chemical composition and so are index-matched. In one specific such example, the substrate 114 can comprise sapphire (i.e., crystalline aluminum oxide) and the inorganic coating medium 116b can comprise aluminum oxide.

Any one or more suitable processes can be employed for forming the phosphor layer 116. In an example of a fabrication method, the luminescent particles 116a can be deposited onto the substrate 114, and then the substrate 114 and the deposited luminescent particles 116a can be coated with the inorganic coating medium 116b. In some examples a deposition process or sequence such as atomic layer deposition (ALD) can be employed to form relatively thin coatings of the inorganic coating medium 116b on the particles 116a and the substrate 114; in some examples the deposited coatings can be between about 200 nm thick and about 700 nm thick; in some examples the deposited coatings can be less than 400 nm thick. The deposition can be arranged to leave voids in the coating medium 116b among the particles 116a within the phosphor layer 116. The deposition process can be tuned or optimized to yield size distribution or density of such voids in a desired range, to yield desired scattering properties for the layer 116. Scattering by the luminescent particles 116a and any voids present in the layer 116 can be selected to achieve desired, improved, or optimized luminance, light outcoupling, or emission angular distribution.

The phosphor layer 116 can be applied directly to the second surface and sidewalls of the substrate 114 somewhat conformally, so that the layer 116 extends at least partly down the sidewalls. In some examples the layer 116 entirely covers the sidewalls of the substrate 114; in some examples the layer 116 also extends over sidewalls of the semiconductor diode structure 112.

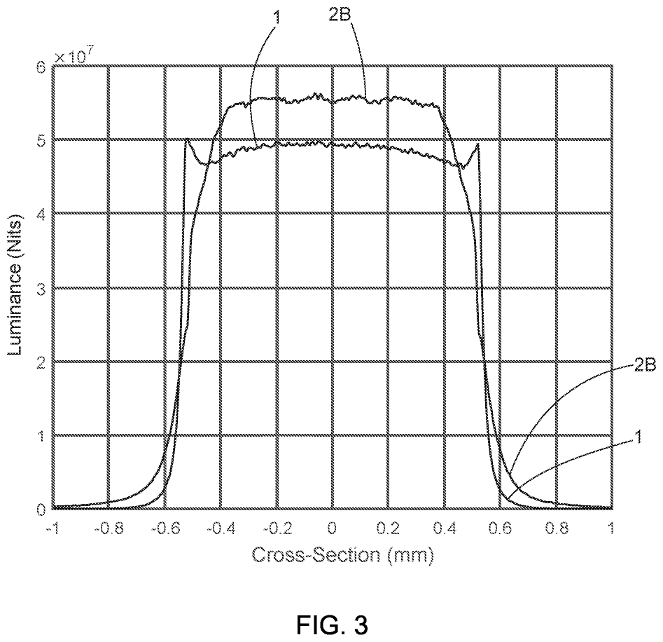

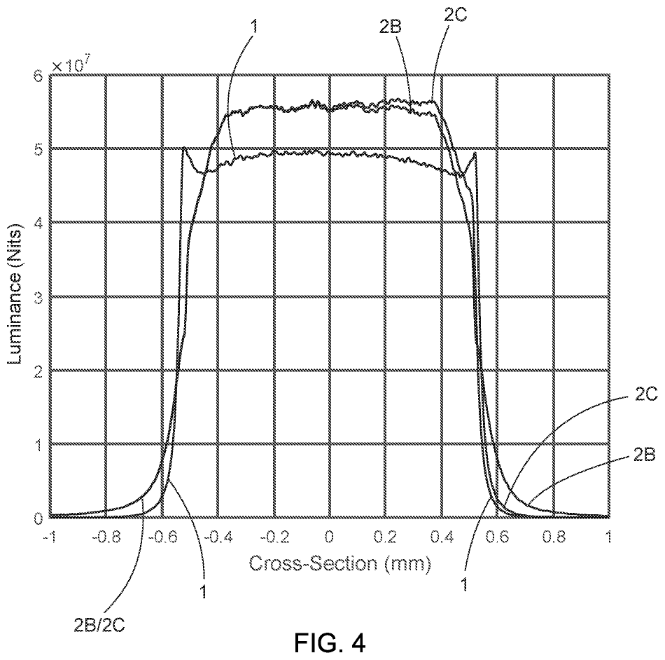

FIG. 3 shows plots 1 and 2B of luminance as a function of position across the light-emitting devices of FIGS. 1 and 2B, respectively. The example inventive device of FIG. 2B exhibits higher luminance across much of the device central area, and shows adequate contrast at the device edges even without an optical side coating to limit lateral propagation of output light. That improved performance is achieved without an optical side coating and without the lateral light collectors of previously disclosed devices. Limiting the thickness of the substrate 114 and the phosphor layer 116 in the device of FIG. 2B, and sufficient scattering within the phosphor payer 116, result in the improved performance relative to the conventional device of FIG. 1. In some examples a light-emitting device arranged as in FIG. 2B can exhibit 2.5% to 3% flux gain, or 12% to 15% luminance gain, relative to an otherwise similar device arranged as in FIG. 1.

The contrast at the device edge of FIG. 2B is not quite as good as the conventional device of FIG. 1, however. FIG. 2C illustrates an optical side coating 120 positioned against one edge of an inventive light-emitting device. FIG. 4 shows plots 1, 2B, and 2C of luminance as a function of position across the light-emitting devices of FIGS. 1, 2B, and 2C respectively. The luminance over their central regions is nearly the same for the devices of FIGS. 2B and 2C and greater than the central luminance exhibited by the conventional device of FIG. 1. The effect of the optical side coating 120 can be seen on the right side of FIG. 4, which shows the inventive device of FIG. 2C exhibiting improved edge contrast relative to the inventive device of FIG. 2B; the edge contrast of the device of FIG. 2C nearly matches the edge contrast of the conventional device of FIG. 1. On the left side of FIG. 4 the curves 2B and 2C nearly coincide, because the structures are the same for both devices on that side (i.e., no optical side coating 120). The obstruction of lateral light propagation by the optical sidewall coating 120 can be effected in any suitable way, e.g., using a reflective or scattering coating or layer, or reflection or scattering at an interface between the wavelength-converting layer 116 and the optical sidewall coating 120, or by absorption or scattering by bulk material of the optical sidewall coating 120 (e.g., titanium oxide scattering particles dispersed in a silicone binder). In examples including an optical side coating 120, it can be of any suitable type, structure, or composition, including any of those just described. In some examples, instead of an optical side coating 120 a metallic shield coating or metallic reflective coating can be employed.

An example method for making an inventive wavelength-converted light-emitting device 100 (A) forming the semiconductor diode structure 112 on the first surface of the substrate 114, (B) forming the wavelength-converting layer 116 on the second surface and sidewalls of the substrate 114, and optionally (C) forming, depositing, or adhering the optical sidewall coating 120. To form the examples of FIGS. 2A/2B/2C, the method can include depositing the luminescent particles 116a onto the second surface and sidewalls of the substrate 114, and then depositing the inorganic medium 116b onto the second surface and sidewalls of the substrate 114 and the deposited luminescent particles 116a.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.

Example 1. A wavelength-converted light-emitting device comprising: (a) a substantially transparent substrate having opposite first and second surfaces and sidewalls connecting the first and second surfaces, a nonzero thickness of the substrate being less than 60 μm; (b) a semiconductor diode structure on the first surface of the substrate, including a light-emitting active region within the semiconductor diode structure that is arranged so as to emit first output light in a first output wavelength range, at least a portion of the first output light entering the substrate through the first substrate surface; and (c) a wavelength-converting layer on the second surface and the sidewalls of the substrate, the wavelength-converting layer comprising a multitude of luminescent particles that are bound together or to the substrate by a transparent inorganic coating medium substantially index-matched with the substrate, a nonzero D50 characterizing the luminescent particles being less than 20 μm, a nonzero thickness of the inorganic coating medium on the luminescent particles being less than 700 nm, a nonzero thickness of the wavelength-converting layer being less than 50 μm, the luminescent particles absorbing incident first output light exiting the substrate and emitting second output light in a second output wavelength range that differs from the first output wavelength range.

Example 2. The device of Example 1, the semiconductor diode structure including one or more III-nitride semiconductor materials or mixtures or alloys thereof.

Example 3. The device of any one of Examples 1 or 2, the nonzero thickness of the substrate being less than 50 μm, less than 40 μm, less than 30 μm, or less than 20 μm.

Example 4. The device of any one of Examples 1 through 3, the nonzero thickness of the wavelength-converting layer being less than 40 μm, less than 30 μm, less than 20 μm, less than 15 μm, or less than about 10 μm.

Example 5. The device of any one of Examples 1 through 4, the nonzero D50 characterizing the luminescent particles being greater than 1 μm, greater than 2 μm, greater than 5 μm, greater than 10 μm, or greater than 15 μm.

Example 6. The device of any one of Examples 1 through 5, the nonzero D50 characterizing the luminescent particles being less than 15 μm, less than 10 μm, less than 5 μm, or less than 2 μm.

Example 7. The device any one of Examples 1 through 6, the nonzero thickness of the inorganic coating medium on each particle being less than 500 nm, less than 400 nm, less than 300 nm, less than 200 nm, or less than 100 nm.

Example 8. The device of any one of Examples 1 through 7, the nonzero thickness of the inorganic coating medium on each particle being greater than 50 nm, greater than 100 nm, greater than 200 nm, greater than 300 nm, greater than 400 nm, or greater than 500 nm.

Example 9. The device of any one of Examples 1 through 8, the wavelength-converting layer including a multitude of voids that result in optical scattering of light propagating within the wavelength-converting layer.

Example 10. The device of any one of Examples 1 through 9, the substrate and the inorganic coating medium having substantially the same chemical composition.

Example 11. The device of any one of Examples 1 through 10, the substrate comprising sapphire and the inorganic coating medium comprising aluminum oxide.

Example 12. The device of any one of Examples 1 through 11 further comprising an optical side coating positioned against the wavelength-converting layer opposite at least one sidewall of the substrate.

Example 13. A method for making the wavelength-converted light-emitting device of any one of Examples 1 through 12, the method comprising: (A) forming the semiconductor diode structure on the first surface of the substrate; and (B) forming on the second surface and the sidewalls of the substrate the wavelength-converting layer.

Example 14. A method for making a wavelength-converted light-emitting device, the method comprising: (A) forming a semiconductor diode structure on a first surface of a substantially transparent substrate, the substrate having opposite first and second surfaces and sidewalls connecting the first and second surfaces, a nonzero thickness of the substrate being less than 60 μm, the semiconductor diode structure including a light-emitting active region within the semiconductor diode structure that is arranged so as to emit first output light in a first output wavelength range, at least a portion of the first output light entering the substrate through the first substrate surface; and (B) forming on the second surface and the sidewalls of the substrate a wavelength-converting layer, the wavelength-converting layer comprising a multitude of luminescent particles that are bound together or to the substrate by a transparent inorganic coating medium substantially index-matched with the substrate, a nonzero D50 characterizing the luminescent particles being less than 20 μm, a nonzero thickness of the inorganic coating medium on the luminescent particles being less than 700 nm, a nonzero thickness of the wavelength converting layer being less than 50 μm, the luminescent particles absorbing incident first output light exiting the substrate and emitting second output light in a second output wavelength range that differs from the first output wavelength range.

Example 15. The method of any one of Examples 13 or 14, the semiconductor diode structure including one or more III-nitride semiconductor materials or mixtures or alloys thereof.

Example 16. The method of any one of Examples 13 through 15, the nonzero thickness of the substrate being less than 50 μm, less than 40 μm, less than 30 μm, or less than 20 μm.

Example 17. The method of any one of Examples 13 through 16, the nonzero thickness of the wavelength-converting layer being less than 40 μm, less than 30 μm, less than 20 μm, less than 15 μm, or less than about 10 μm.

Example 18. The method of any one of Examples 13 through 17, the nonzero D50 characterizing the luminescent particles being greater than 1 μm, greater than 2 μm, greater than 5 μm, greater than 10 μm, or greater than 15 μm.

Example 19. The method of any one of Examples 13 through 18, the nonzero D50 characterizing the luminescent particles being less than 15 μm, less than 10 μm, less than 5 μm, or less than 2 μm.

Example 20. The method of any one of Examples 13 through 19, a nonzero thickness of the inorganic coating medium on each particle being less than 500 nm, less than 400 nm, less than 300 nm, less than 200 nm, or less than 100 nm.

Example 21. The method of any one of Examples 13 through 20, the nonzero thickness of the inorganic coating medium on each particle being greater than 50 nm, greater than 100 nm, greater than 200 nm, greater than 300 nm, greater than 400 nm, or greater than 500 nm.

Example 22. The method of any one of Examples 13 through 21, the wavelength-converting layer including a multitude of voids that result in optical scattering of light propagating within the wavelength-converting layer.

Example 23. The method of any one of Examples 13 through 22, the substrate and the inorganic coating medium having substantially the same chemical composition.

Example 24. The method of any one of Examples 13 through 23, the substrate comprising sapphire and the inorganic coating medium comprising aluminum oxide.

Example 25. The method of any one of Examples 13 through 24, wavelength-converting layer being formed by first depositing a layer of the luminescent particles onto the second surface and sidewalls of the substrate, and then forming the inorganic coating medium using an atomic layer deposition (ALD) sequence.

Example 26. The method of any one of Examples 13 through 25 further comprising forming an optical side coating positioned against the wavelength-converting layer opposite at least one sidewall of the substrate.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112 (f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112 (f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A wavelength-converted light-emitting device comprising:
(a) a substantially transparent substrate having opposite first and second surfaces and sidewalls connecting the first and second surfaces, a nonzero thickness of the substrate being less than 60 μm;
(b) a semiconductor diode structure on the first surface of the substrate, including a light-emitting active region within the semiconductor diode structure that is arranged so as to emit first output light in a first output wavelength range, at least a portion of the first output light entering the substrate through the first substrate surface; and
(c) a wavelength-converting layer on the second surface and the sidewalls of the substrate, the wavelength-converting layer comprising a multitude of luminescent particles that are bound together or to the substrate by a transparent inorganic coating medium substantially index-matched with the substrate, a nonzero D50 characterizing the luminescent particles being less than 20 μm, a nonzero thickness of the inorganic coating medium on the luminescent particles being less than 700 nm, a nonzero thickness of the wavelength-converting layer being less than 50 μm, the luminescent particles absorbing incident first output light exiting the substrate and emitting second output light in a second output wavelength range that differs from the first output wavelength range.

2. The device of claim 1, the semiconductor diode structure including one or more III-nitride semiconductor materials or mixtures or alloys thereof.

3. The device of claim 1, the nonzero thickness of the substrate being less than 50 μm.

4. The device of claim 1, the nonzero thickness of the wavelength-converting layer being less than 30 μm.

5. The device of claim 1, the nonzero D50 characterizing the luminescent particles being less than 10 μm.

6. The device of claim 1, the nonzero thickness of the inorganic coating medium on each particle being less than 400 nm.

7. The device of claim 1, the wavelength-converting layer including a multitude of voids that result in optical scattering of light propagating within the wavelength-converting layer.

8. The device of claim 1, the substrate and the inorganic coating medium having substantially the same chemical composition.

9. The device of claim 1, the substrate comprising sapphire and the inorganic coating medium comprising aluminum oxide.

10. The device of claim 1 further comprising an optical side coating positioned against the wavelength-converting layer opposite at least one sidewall of the substrate.

11. A method for making a wavelength-converted light-emitting device, the method comprising:
(A) forming a semiconductor diode structure on a first surface of a substantially transparent substrate, the substrate having opposite first and second surfaces and sidewalls connecting the first and second surfaces, a nonzero thickness of the substrate being less than 60 μm, the semiconductor diode structure including a light-emitting active region within the semiconductor diode structure that is arranged so as to emit first output light in a first output wavelength range, at least a portion of the first output light entering the substrate through the first substrate surface; and
(B) forming on the second surface and the sidewalls of the substrate a wavelength-converting layer, the wavelength-converting layer comprising a multitude of luminescent particles that are bound together or to the substrate by a transparent inorganic coating medium substantially index-matched with the substrate, a nonzero D50 characterizing the luminescent particles being less than 20 μm, a nonzero thickness of the inorganic coating medium on the luminescent particles being less than 700 nm, a nonzero thickness of the wavelength converting layer being less than 50 μm, the luminescent particles absorbing incident first output light exiting the substrate and emitting second output light in a second output wavelength range that differs from the first output wavelength range.

12. The method of claim 11, the semiconductor diode structure including one or more III-nitride semiconductor materials or mixtures or alloys thereof.

13. The method of claim 11, the nonzero thickness of the substrate being less than 50 μm.

14. The method of claim 11, the nonzero thickness of the wavelength-converting layer being less than 30 μm.

15. The method of claim 11, the nonzero D50 characterizing the luminescent particles being less than 10 μm.

16. The method of claim 11, the nonzero thickness of the inorganic coating medium on each particle being less than 400 nm.

17. The method of claim 11, the wavelength-converting layer including a multitude of voids that result in optical scattering of light propagating within the wavelength-converting layer.

18. The method of claim 11, (i) the substrate and the inorganic coating medium having substantially the same chemical composition, or (ii) the substrate comprising sapphire and the inorganic coating medium comprising aluminum oxide.

19. The method of claim 11, wavelength-converting layer being formed by first depositing a layer of the luminescent particles onto the second surface and sidewalls of the substrate, and then forming the inorganic coating medium using an atomic layer deposition (ALD) sequence.

20. The method of claim 11 further comprising forming an optical side coating positioned against the wavelength-converting layer opposite at least one sidewall of the substrate.
